(19) United States
(12) Patent Application Publication
(10) Pub. No.: US 2023/0408269 A1
(43) Pub. Date: Dec. 21, 2023

(54) ROUTE SUMMARY CONSTRUCTION, COMPRESSION AND DECOMPRESSION

(71) Applicant: FORD GLOBAL TECHNOLOGIES, LLC, Dearborn, MI (US)

(72) Inventors: Omar Makke, Lyon Township, MI (US); Jeremy Lerner, Southfield, MI (US)

(21) Appl. No.: 17/844,098

(22) Filed: Jun. 20, 2022

(51) Int. Cl. G01C 21/34

(52) U.S. Cl. CPC G01C 21/3446; G01C 21/3492; G01C 21/343

(57) ABSTRACT

A system includes a processor that determines a route. The processor determines a plurality of nodes along the route and alternative paths from one node to a successive node along the route through another node. The processor defines the route based on the plurality of nodes and removes at least one node between second and third nodes on the basis that the removed node lies along a least-cost path between the second and third nodes. The processor repeats removal of nodes until a set of minimum nodes to define the route with all non-least-cost path decisions is achieved as a compressed route and transmits the compressed route to at least one second processor that decompresses the compressed route through inclusion of removed nodes, the removed nodes being re-included on the basis of being nodes lying on a least-cost path between two nodes included sequentially in the compressed route.

### TECHNICAL FIELD

The illustrative embodiments generally relate to methods and apparatuses for route summary construction, compression and decompression.

### BACKGROUND

Global positioning systems and navigation systems have made vehicle navigation easier than ever. Instead of reaching for a map, or asking for directions, drivers can simply enter a destination and a series of decisions can be made as to which roads between a present location and the desired destination represent a preferred path.

Since the vehicles are using digital information to devise the routes, the data for a given route is available, at least temporarily, in a vehicle computer. Further, and deviances from the route or preferred routings are available (e.g., if a driver requests to route-around a path or take an alternative, seemingly longer path). Many entities could benefit from this information, but people may prefer not to be tracked in this manner.

Tying a given vehicle at a given location together with a given time may give a highly accurate snapshot of a route, but may be considered to be too personal to be shared with others, either with an original equipment manufacturer or another third party. Drivers may, however, be willing to share data that represented a route, but which did not effectively constitute tracking, which was anonymized and generally just described the route without necessarily knowing the location of the specific vehicle along the route at any given moment or even possibly ever.

### SUMMARY

In a first illustrative embodiment, a system includes at least one first processor configured to determine a route to an input destination. The processor is also configured to determine a plurality of nodes, representing decision points, along the route and alternative paths from one node to a successive node along the route through another node. The processor is further configured to define the route based on the plurality of nodes. Also, the processor is configured to remove at least one first node between second and third nodes on the defined route, the removed first node being removed on the basis that it lies along a least-cost path between the second and third nodes. The processor is additionally configured to repeat removal of nodes until a set of minimum nodes to define the route with all non-least-cost path decisions is achieved as a compressed route and transmit the compressed route to at least one second processor.

The second processor is configured to decompress the compressed route through inclusion of removed nodes, the removed nodes being re-included on the basis of being nodes lying on a least-cost path between two nodes included sequentially in the compressed route.

In a second illustrative embodiment, a method includes determining a route to an input destination and determining a plurality of nodes, representing decision points, along the route and alternative paths from one node to a successive node along the route through another node. The method further includes defining the route based on the plurality of nodes and removing at least one first node between second and third nodes on the defined route, the removed first node being removed on the basis that it lies along a least-cost path between the second and third nodes. The method also includes repeating removal of nodes until a set of minimum nodes to define the route with all non-least-cost path decisions is achieved as a compressed route. The method further includes transmitting the compressed route to another computing device and receiving the compressed route at the additional computing device. The additional computing device is configured to perform a method comprising decompressing the compressed route through inclusion of removed nodes, the removed nodes being re-included on the basis of being nodes lying on a least-cost path between two nodes included sequentially in the compressed route.

In a third illustrative embodiment, a non-transitory computer-readable storage medium stores instructions that, when executed, cause one or more executing processors to perform a method comprising determining a route to an input destination and determining a plurality of nodes, representing decision points, along the route and alternative paths from one node to a successive node along the route through another node. The method further includes defining the route based on the plurality of nodes and removing at least one first node between second and third nodes on the defined route, the removed first node being removed on the basis that it lies along a least-cost path between the second and third nodes. The method also includes repeating removal of nodes until a set of minimum nodes to define the route with all non-least-cost path decisions is achieved as a compressed route. The method further includes transmitting the compressed route to another computing device and receiving the compressed route at the additional computing device. The additional computing device is configured to perform a method comprising decompressing the compressed route through inclusion of removed nodes, the removed nodes being re-included on the basis of being nodes lying on a least-cost path between two nodes included sequentially in the compressed route.

### BRIEF DESCRIPTION OF THE DRAWINGS

FIG. 1 shows an illustrative vehicle reporting system and cloud decompression system;

FIGS. 2A and 2B show an illustrative route representation and an illustrative process for assembling a summary of the route, respectively;

FIG. 3 shows an illustrative node retention process;

FIG. 4 shows an illustrative example route and alternative pathing; and

FIG. 5 shows an illustrative decompression process.

### DETAILED DESCRIPTION

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative basis for teaching one skilled in the art to variously employ the present invention. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

In addition to having exemplary processes executed by a vehicle computing system located in a vehicle, in certain embodiments, the exemplary processes may be executed by a computing system in communication with a vehicle computing system. Such a system may include, but is not limited to, a wireless device (e.g., and without limitation, a mobile phone) or a remote computing system (e.g., and without limitation, a server) connected through the wireless device. Collectively, such systems may be referred to as vehicle associated computing systems (VACS). In certain embodiments, particular components of the VACS may perform particular portions of a process depending on the particular implementation of the system. By way of example and not limitation, if a process has a step of sending or receiving information with a paired wireless device, then it is likely that the wireless device is not performing that portion of the process, since the wireless device would not “send and receive” information with itself. One of ordinary skill in the art will understand when it is inappropriate to apply a particular computing system to a given solution.

Execution of processes may be facilitated through use of one or more processors working alone or in conjunction with each other and executing instructions stored on various non-transitory storage media, such as, but not limited to, flash memory, programmable memory, hard disk drives, etc. Communication between systems and processes may include use of, for example, Bluetooth, Wi-Fi, cellular communication and other suitable wireless and wired communication.

In each of the illustrative embodiments discussed herein, an exemplary, non-limiting example of a process performable by a computing system is shown. With respect to each process, it is possible for the computing system executing the process to become, for the limited purpose of executing the process, configured as a special purpose processor to perform the process. All processes need not be performed in their entirety, and are understood to be examples of types of processes that may be performed to achieve elements of the invention. Additional steps may be added or removed from the exemplary processes as desired.

With respect to the illustrative embodiments described in the figures showing illustrative process flows, it is noted that a general purpose processor may be temporarily enabled as a special purpose processor for the purpose of executing some or all of the exemplary methods shown by these figures. When executing code providing instructions to perform some or all steps of the method, the processor may be temporarily repurposed as a special purpose processor, until such time as the method is completed. In another example, to the extent appropriate, firmware acting in accordance with a preconfigured processor may cause the processor to act as a special purpose processor provided for the purpose of performing the method or some reasonable variation thereof.

While OEMs and other parties may want to analyze route data for general driving habits, drivers may not want to share overly complete data sets with these parties, such as data representing given locations at given times of a given vehicle. The illustrative embodiments propose illustrative methods and forms of route summaries that allow a route to be effective summarized in a compressed manner and which should alleviate most, if not all, privacy concerns. If the data was anonymized, the only thing an OEM might know, for example, is that a given SUV took a given route, represented by the summary, at a given time. There would be no necessary reporting of which SUV or when the SUV was even at a portion of the route. The summary can be succinct and reported with relative anonymity.

Of course, some users may not want to have their routes shared at all, and could opt out, but by providing a summary path and method of compressing and reporting a route, many users may be encouraged to share their data, knowing it does not tie back to them or their exact locations at exact moments in time.

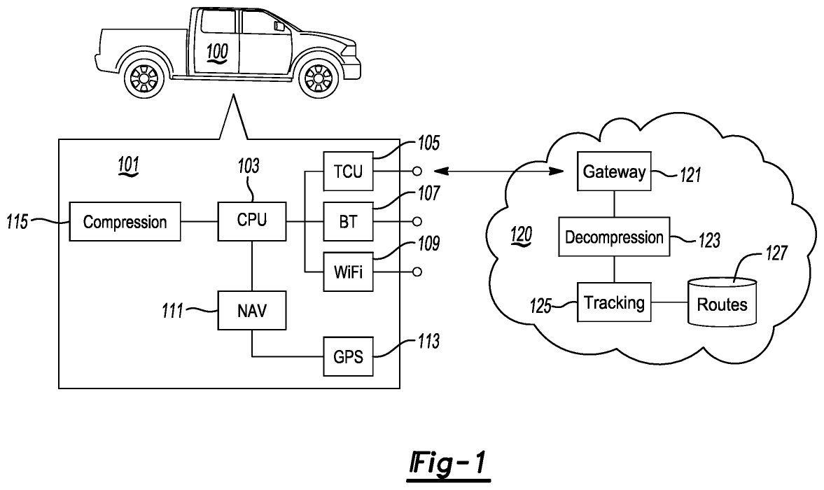

FIG. 1 shows an illustrative vehicle reporting system and cloud decompression system. In this example, the vehicle 100 includes a vehicle computing system 101. This includes one or more CPUs 103, as well as communication transceivers such as, but not limited to, a telematics control unit (TCU) 105, a BLUETOOTH transceiver 107, a Wi-Fi transceiver 109, etc. The telematics control unit 105 may be used for communication with the cloud 120, which, in this example, may be a place where route summaries are received and decompressed to reconstruct full routes from a summary.

The vehicle 100 may also include a navigation unit 111 with a GPS 113, although mobile devices may provide the navigation and GPS functionality as well, conveying information to the vehicle 100 through the BLUETOOTH connection, for example, or a wired connection. Moreover, this same type of route summary could be used to share route data from a mobile device, although to use this summary for, for example, a walking path, may be a bit more complex, as the route is assembled based on known paths between nodes and someone could theoretically walk virtually anywhere, whether it was indicated as passable territory or not. Nonetheless, pathing for vehicles, bicycles, and even people, could be achieved.

The vehicle 100, or mobile device if the information is being shared directly from the mobile device, could also include a compression process, which serves to compress the route into a summary of critical route points from which a full route can be reassembled.

The cloud may include a gateway process 121 for communication handling, which, in this case, could direct route summaries to a decompression process 123 which can reassemble the route from the summary and share the information with a data tracking process 125, which, while it may remain ignorant of user information, can still track how vehicles are generally used and at what times. This information can be stored in one or more route databases 127, which may be used to provide future routing assistance and general guidance for drivers as to what routes are preferred at what times. For example, local drivers may know that a certain road has school traffic thereon from 3:30-4:15, and thus should be circumvented, even though a map may show no general reason to circumvent this. A significant number of vehicles electing to circumvent this road from 3:30-4:15 may reveal a premise that the road should be circumvented, and allow advising other drivers to circumvent the road.

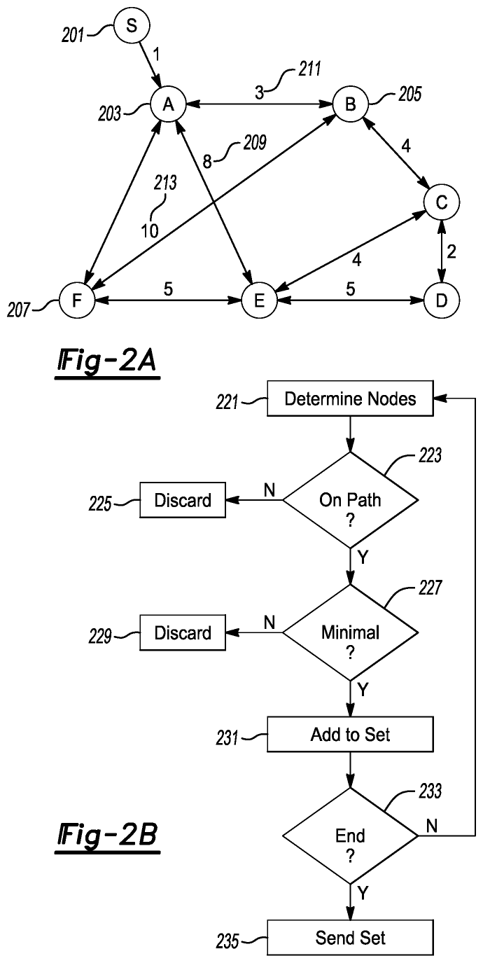

FIGS. 2A and 2B show an illustrative route representation and an illustrative process for assembling a summary of the route, respectively. FIG. 2A shows a contemplation of a route as a series of nodes, wherein each node is a location where one or more possible decisions may be made (e.g., without limitation, an intersection of possible roads).

The S node 201 may be a starting point, where the driver is currently located when a route is begun or a route request is made. The A node 203 may be the initial decision point along the route. While other features, other than intersections can comprise nodes, the examples are presented with respect to intersections of roads. Nodes B 205 and F 207 are reachable from the intersection of node A, and each may have a travel cost associated therewith, such as cost 3 211 from A 203 to B 205. B can be reached by travel through F as well, but at a cost of 16 (6 to travel from A 205 to F 207, and to travel from F 207 to B 205).

Since road networks may be effectively endless, it may be worth bounding the graph with maximum cost parameters and/or retracing parameters. For example, the cost between at least one node on the graph and at least another node connected directly to that node may have to be no less than X. So, for example, if X was 5, then all of the nodes shown are properly included, but if X were 4, then node F 207 may be excluded because it has no single path of 4 cost. Once a node is included, the other paths between the node and other nodes in the graph may be included, even if they exceed the maximum single path cost, but this would assure that each included node had at least one low cost connection to another node.

Other bounding may include non-retracing boundaries. For example, node G (not shown) may also be accessible through node A 203, but to reach any other node of the graph from G may require retracing through A, and so, unless G was expressly included in the route as a waypoint, there may be no reason to include G in the set for contemplation.

The set shown is the set from which a minimum descriptive path will be derived, and so inclusion of extra nodes that will be dropped from contemplation does not necessarily result in any additional useful information, as those nodes, if not expressly designated, will not be included in the minimum summary in any event.

For purposes of this example, a path of A, B, C, E, D will be contemplated. Another bounding rule may be that any node that leads to one included node element from another node element should be included, so node F could be included regardless of distance as it represents at least one path from node A to node E, and both A and E are in the direct path of actual planned travel. Whether that node (F) for inclusion must include a one-hop or N-hop path can be a further constraint—i.e., another path that is 5 hops may not be included, unless expressly included, as the path is too deviant. In this instance, travel from A to E can be achieved by a number of paths that are actually lower cost or equal to the planned path, such as A to E directly at a cost of 8 209, or A to F to E which also costs 11 (as does the planned path). That too could be a predicate for inclusion of a node—namely, that the cost of travel through that node to another node along the expressly intended path cost no more than the intended path of travel (which would properly include F because the cost of the alternative A→F→E is the same as the cost of the planned A→B→C→E).

The node graph shown in 2A will be used as the basis for compression of a route to represent the minimal data set usable to recreate the route, and the decompression process can recreate the route as long as it has the same costs assigned to each segment between nodes. Accordingly, unless travel times are fixed, travel time may not be the ideal value to assign, because it can vary with time, and decompression would require a snapshot of the same data contemplated by the compression algorithm. Distance, however, is largely fixed, and is almost expressly fixed when one does not account for things like detours. So, from a perspective of a static map, every map should show the same distance and so this may be a more suitable cost assignment in terms of using the same values for reconstruction. The distance “cost” may not be the focus of interest in any event, and so it may be reasonable to use a value that is fixed between entities, whether or not some other “cost” such as travel time or road characteristics is later interposed on the reconstructed data set.

The process may determine a route as in FIG. 2B, which includes a set of nodes that reflect, for whatever reason, the planned route. This could be, for example, the fact that those selected nodes represent the present fastest route, even if not the lowest cost in terms of distance, or the nodes could be selected based on the inclusion of waypoints or for other reasons. Eventually, however, the navigation unit or process would provide a route that, for this example, intends to pass from S to A to B to C to E to D.

The path travels from S to a first node A at 221, where a first branch occurs and A is a premise node to be contemplated. Examining the graph of nodes, the process can progress from S to A and then looks at the possible nodes branching from A, at 223. If a possible node is on the path, in order, it can be considered for inclusion in the minimal set, such as node B. Node F is not on the path, and node E is not on the path in the preferred order, so those nodes can be discarded for inclusion in the minimal set (at this moment in time) at 225. For node B, the process can then determine if the lowest cost path from S to B includes node A (the prior node) and no other nodes at 227. Thus, the path from S to B is the minimal cost path and therefore A can be discarded, because if one knows that S and B are on the path, any reconstruction of the minimal cost path will reveal A.

If the path is not the minimal path, then A will be left in, otherwise a reconstruction will come to an invalid conclusion if based on the preceding premise. So B is added to the set at 231 and node A is discarded from the set and if nodes remain (i.e., if B is not the destination), then the process repeats, this time determining node B as the premise node at 221, ignoring F for the previous reasons, and contemplating the lowest cost path from S to C, which does include B, resulting in inclusion of C and discarding of B. Again, a path from S to C based on the lowest cost will reveal B and A simply through inclusion of C and the correct reconstruction process.

Once the contemplation reaches node E, it determines that the lowest cost path from S to E is not A, B, C, but rather A, so C will be retained at 231 and E will be added to the set, so that the information conveyed by C, namely, the inclusion of A and B in the correct path, will not be lost in a reconstruction that would conclude that the vehicle traveled from S to A to E. The same is true with node D, having been intentionally reached via A, B, C, E, but having a lowest cost path of A, B, C, so that node E is also retained at 231, resulting in a path of S, C, E, D for a final compressed path, which can be sent to the cloud at 235 upon concluding at 233 that D is the destination node.

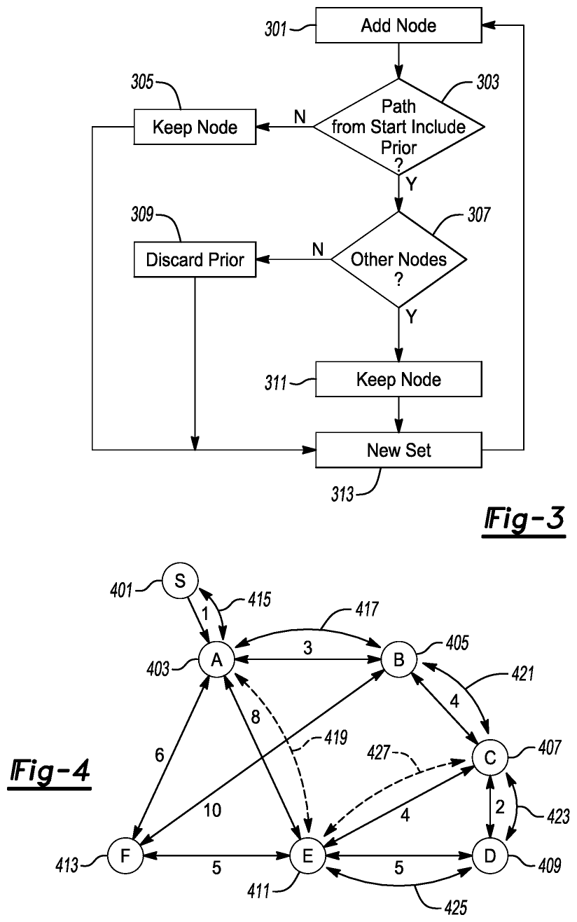

FIG. 3 shows an illustrative node retention process. In this example, the decision to retain or discard a node from a known path is examined in illustrative detail. A node is added to the path based on the intended route at 301, and the process may also examine whether the lowest cost path from the start to the node includes the immediately prior node at 303. That is one of two predicates, and if true, the process may further examine whether there are additional nodes in that path at 307. Discarded nodes are not counted as additional nodes, in this example, since they have been removed and the path through the non-discarded prior node (B) reveals the existence of A and effectively renders B a “super-node” that includes A and B by conveyance of information of the fact of the existence of B in the final path (up to that point). Similarly, when C is retained, retention of C indicates the fact of A and B based on the lowest-cost path premise, and so C is effectively representative of A, B and C, and so those represented nodes count as “one node” for the question of whether the lowest cost path from S to N includes other nodes other than the prior node.

If the lowest cost path from S to the node (using E as an example) is not achieved based on the planned path (a path through C with a cost of 8 to reach C) at 303, then the node (C in this case) is kept at 305. If there were other nodes on the path other than C, then the node would have been kept as well at 311, since a least-cost path may be reduced to a single node. Thus, any non-discarded nodes remaining on a path from S to the N node under current contemplation were necessary inclusions to map out a non-least-cost path and should be retained.

If the lowest cost path from S to the current node does not include more than one node (or one supernode as above), then the prior node (the single node or super node from which the current node was reached) is discarded at 309, as the current node is sufficiently representative of the prior node and all nodes that the prior node also represented. The retained node(s) are added to a new set at 313 and the process moves to a next node, unless the destination has been reached.

FIG. 4 shows an illustrative example route and alternative pathing. As can be seen from FIG. 4, there are many paths from the start node 401 to destination node D 409. A 403 is necessary for any path, but subsequent paths to D can include F 413, E 411, and B 405. Moreover, the path to E 411, which is still on an intended path A, B, C, E, D, is less costly from A directly to E, but the route of B, C, D may still be taken for a variety of reasons.

Visually speaking, the hops from A to E 419 and from C to D 427, represent less costly hops than those elected to be taken, and thus represent a location where a prior node should likely be included. If a path includes E, but is not directly from A to E, then whether that path goes through F or C (the other ways of reaching E), F or C, at least, will be included. Similarly, any path that passes through C and D, but is not direct from C to D (the lowest cost path), will include intermittent nodes (E in this case) that are on a more costly path.

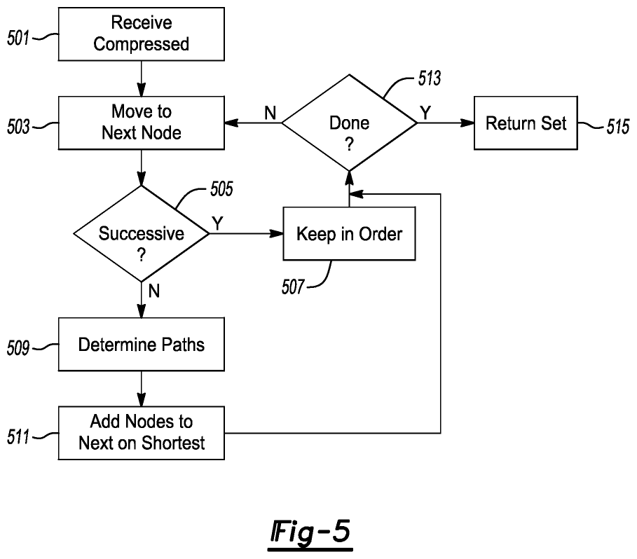

FIG. 5 shows an illustrative decompression process, described in conjunction with FIG. 4. A decompression process receives a compressed path at 501 and moves from a start node to a next node in the explicit path at 503. If the compressed path is S, C, E, D, then the process begins at the start node and moves along the graph shown in FIG. 4 to node C. The movement is along the least costly path, represented by hops 417 and 421, and having a cost of 1 (S→A)+3 (A→B)+4 (B→C). Since no other paths to C have a lesser cost, the decompression process will take the correct path to C.

If the next node in the list (C) is not the successive node on the graph (the node following the current node S, in this instance), then there will be a need to add back missing nodes. If the next node in the compressed list were A, then there would be no intervening nodes to be added. Since C is not successive to S, the process determines the lowest cost path traveled to C at 509 and adds back in all nodes along that path at 511, resulting in a partial decompression of S, A, B, C . . . .

Since S is not the destination node at 513, the process moves to the next node (C) and considers the subsequent node in the list (E in this instance). E is a successive node to C (one hop node, via hop 423) and so E is kept on the decompression list at the location following C at 507 (no intervening nodes are added). A similar conclusion is drawn while contemplating E with regards to the next node D, and D is also left, and by such a process S, C, E, D becomes S, A, B, C, E, D. This could be done for any number of nodes with relative quickness, as long as the compression and decompression entities have the same data (costs, in this case) and operate under the same premise (e.g., that the least costly path is the “correct” path to find missing data, in this case). The result is an easily compressed and decompressed route, allowing drivers to remain anonymous and allowing for transfer of less than all data pertaining to a route path, but still allowing for reconstruction of the route path.

Updated data sets representing deviances from the plan can also be sent (if the route is sent in advance) upon deviance and/or can be added to the existing set if the route is sent subsequent to travel. For example, if a user takes a single detour to another location and then chains back to the route, or retravels back to the route, the data set representing the actual route can be easily recalculated. If the user went on a cost 1 deviance and returned on the same deviance, this could be represented by, for example, twice inclusion of the branching node with a deviance node in between or the least-cost path model with only a single inclusion of the branching node. For example, if Q were a branch off of B, and the user drove down a road to Q, from B, and then back to B to resume the route, the modified set would be S, Q, B, C, E, D. Since (assuming there are no other paths to Q) the path from S to Q includes A and B, those could still be omitted, but upon reaching B the second time (returning from Q) the path S, A, B, Q is not the lowest cost route to B, the lowest cost route is S, A, then the B node would be included after the Q node deviance.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to strength, durability, marketability, appearance, packaging, size, serviceability, weight, manufacturability, ease of assembly, etc. As such, embodiments described as less desirable than other embodiments or prior art implementations with respect to one or more characteristics are not outside the scope of the disclosure and can be desirable for particular applications.

What is claimed is:

1. A system comprising:
at least one first processor configured to:
determine a route to an input destination;
determine a plurality of nodes, representing decision points, along the route and alternative paths from one node to a successive node along the route through another node;
define the route based on the plurality of nodes;
remove at least one first node between second and third nodes on the defined route, the removed first node being removed on the basis that it lies along a least-cost path between the second and third nodes;
repeat removal of nodes until a set of minimum nodes to define the route with all non-least-cost path decisions is achieved as a compressed route; and
transmit the compressed route to at least one second processor;
the at least one second processor configured to:
decompress the compressed route through inclusion of removed nodes, the removed nodes being re-included on the basis of being nodes lying on a least-cost path between two nodes included sequentially in the compressed route.

2. The system of claim 1, wherein the first and second processors respectively determine the least-cost path between the second and third nodes and the least-cost path between two nodes included sequentially in the compressed route based on the same cost data.

3. The system of claim 2, wherein the cost data is based on distance between the nodes.

4. The system of claim 2, wherein the cost data is based on projected travel time between the nodes, determined at a fixed point in time.

5. The system of claim 1, wherein the nodes correspond to intersections along the route.

6. The system of claim 1, wherein the nodes are determined based on boundaries defining node-inclusion, the boundaries including at least a requirement that the node have at least one path to a node

7. The system of claim 1, wherein the at least one first processor is included in a vehicle or a mobile device.

8. A method comprising:
determining a route to an input destination;
determining a plurality of nodes, representing decision points, along the route and alternative paths from one node to a successive node along the route through another node;
defining the route based on the plurality of nodes;
removing at least one first node between second and third nodes on the defined route, the removed first node being removed on the basis that it lies along a least-cost path between the second and third nodes;
repeating removal of nodes until a set of minimum nodes to define the route with all non-least-cost path decisions is achieved as a compressed route;
transmitting the compressed route;
receiving the compressed route; and
decompressing the compressed route through inclusion of removed nodes, the removed nodes being re-included on the basis of being nodes lying on a least-cost path between two nodes included sequentially in the compressed route.

9. The method of claim 8, wherein the removing the at least one first node and re-including the removed nodes is based on the same cost data.

10. The method of claim 9, wherein the cost data is based on distance between the nodes.

11. The method of claim 9, wherein the cost data is based on projected travel time between the nodes, determined at a fixed point in time.

12. The method of claim 8, wherein the nodes correspond to intersections along the route.

13. The method of claim 8, wherein the nodes are determined based on boundaries defining node-inclusion, the boundaries including at least a requirement that the node have at least one path to a node.

14. A non-transitory computer-readable storage medium storing instructions that, when executed, cause one or more executing processors to perform a method comprising:
determining a route to an input destination;
determining a plurality of nodes, representing decision points, along the route and alternative paths from one node to a successive node along the route through another node;
defining the route based on the plurality of nodes;
removing at least one first node between second and third nodes on the defined route, the removed first node being removed on the basis that it lies along a least-cost path between the second and third nodes;
repeating removal of nodes until a set of minimum nodes to define the route with all non-least-cost path decisions is achieved as a compressed route;
transmitting the compressed route;
receiving the compressed route; and
decompressing the compressed route through inclusion of removed nodes, the removed nodes being re-included on the basis of being nodes lying on a least-cost path between two nodes included sequentially in the compressed route.

15. The storage medium of claim 14, wherein the removing the at least one first node and re-including the removed nodes is based on the same cost data.

16. The storage medium of claim 15, wherein the cost data is based on distance between the nodes.

17. The storage medium of claim 15, wherein the cost data is based on projected travel time between the nodes, determined at a fixed point in time.

18. The storage medium of claim 14, wherein the nodes correspond to intersections along the route.

19. The storage medium of claim 14, wherein the nodes are determined based on boundaries defining node-inclusion, the boundaries including at least a requirement that the node have at least one path to a node.
